(19) United States
(12) Patent Application Publication
(10) Pub. No.: US 2021/0325780 A1
(43) Pub. Date: Oct. 21, 2021

(54) METHOD FOR PRODUCING RESIST FILM

(71) Applicant: Tokyo Electron Limited, Tokyo (JP)

(72) Inventors: Kazuki YAMADA, Nirasaki-shi, Yamanashi (JP); Kyohei KOIKE, Tokyo (JP); Masatoshi YAMATO, Miyagi (JP); Hidetami YAEGASHI, Tokyo (JP)

(21) Appl. No.: 17/273,183

(22) PCT Filed: Aug. 22, 2019
(86) PCT No.: PCT/JP2019/032733

§ 371 Date: Mar. 3, 2021

(30) Foreign Application Priority Data
Sep. 5, 2018 (JP) 2018-166018

(51) Int. Cl. G03F 7/004; H01L 21/027; G03F 7/16

(52) U.S. Cl. CPC G03F 7/0042; G03F 7/168; H01L 21/0274

(57) ABSTRACT

A method of producing a resist film includes: a laminating step of fabricating a workpiece by laminating the resist film on an etching target film; and an infiltration step of exposing the workpiece to a gas of a precursor containing a metal having a higher EUV light absorption rate than carbon to infiltrate the metal into the resist film.

This is a National Phase Application filed under 35 U.S.C. 371 as a national stage of PCT/JP2019/032733, filed Aug. 22, 2019, an application claiming the benefit of Japanese Application No. 2018-166018, filed Sep. 5, 2018, the content of each of which is hereby incorporated by reference in its entirety.

### TECHNICAL FIELD

Various aspects and embodiments of the present disclosure relate to a method for producing a resist film.

### BACKGROUND

In lithography technology, for example, selective exposure is performed on a resist film laminated on a substrate using light through a mask on which a predetermined pattern is formed, and development processing is performed so as to form a pattern of a predetermined shape on the resist film. In recent years, with the miniaturization of semiconductor devices, miniaturization is also progressing in lithography technology. Examples of the miniaturization method include shortening the wavelength of an exposure light source. In recent years, exposure using a KrF excimer laser or an ArF excimer laser has been performed. In addition, a lithography technique using extreme ultraviolet (EUV) light having a shorter wavelength than these excimer lasers has also been investigated.

A resist film material is required to have lithography characteristics such as a sensitivity to these exposure light sources and a resolution capable of reproducing fine dimensional patterns. As a resist material satisfying this requirement, for example, a chemically amplified resist composition containing a base material component, the solubility of which is changed in a developing solution by the action of an acid, and an acid generator component, which generates an acid by exposure, may be used.

The reaction mechanism of lithography using EUV light is different from that of lithography using an excimer laser. In addition, in the lithography using EUV light, the goal is to form a fine pattern of several tens of nm. As the size of the resist pattern becomes smaller as described above, a resist composition having a higher sensitivity to the exposure light source is required. Acrylic resins and the like, which are organic compounds, are used as base material components of a resist composition used in excimer laser lithography, but general-purpose acrylic resins and the like have a low EUV light absorption rate.

Therefore, the use of a resist composition containing a complex containing a metal having a higher EUV light absorption rate than carbon, such as hafnium (Hf) or zirconium (Zr), as a base material component has been investigated (see, for example, Patent Document 1 below).

### PRIOR ART DOCUMENTS

### Patent Documents

Patent Document 1: Japanese Laid-Open Patent Publication No. 2015-108781

The present disclosure provides a technique capable of producing a resist film having a high EUV light absorption rate and high shape stability.

### SUMMARY

One embodiment of the present disclosure relates to a method of producing a resist film including a laminating step and an infiltration step. In the laminating step, a workpiece is fabricated by laminating a resist film on an etching target film. In the infiltration step, the workpiece is exposed to a precursor gas containing a metal having a higher EUV light absorption rate than carbon to infiltrate the metal into the resist film.

According to various aspects and embodiments of the present disclosure, it is possible to produce a resist film having a high EUV light absorption rate and high shape stability.

### BRIEF DESCRIPTION OF DRAWINGS

FIG. 1 is a flowchart illustrating an exemplary method of producing a resist film according to a first embodiment of the present disclosure.

FIG. 2 is a schematic cross-sectional view illustrating an exemplary workpiece.

FIG. 3 is a schematic cross-sectional view illustrating an exemplary modification apparatus.

FIG. 4 is a diagram showing an exemplary EUV light absorption rate for each atom.

FIG. 5 is a diagram showing an exemplary tellurium distribution in the depth direction of a resist film.

FIG. 6 is a diagram showing an exemplary light emission intensity for each bond energy in a resist film after modification treatment.

FIG. 7 is a diagram showing an exemplary relationship between an EUV light absorption amount and line edge roughness (LER).

FIG. 8 is a flowchart illustrating an exemplary method of producing a resist film according to a second embodiment of the present disclosure.

### DETAILED DESCRIPTION

Hereinafter, embodiments of a method of producing a resist film disclosed herein will be described in detail with reference to the drawings. The method of producing a resist film disclosed herein is not limited by the following embodiments.

When metal particles are mixed with a liquid organic resin material, the resin material may become gel-like. When a resin material becomes gel-like, it is difficult to control the thickness or the distribution of the thickness thereof in the resist film. In addition, even if the thickness of a resist film or the like is controlled to a predetermined state, the thickness or the distribution of the thickness of the resist film may change due to a change over time, and the stability of the shape of the resist film becomes low. Therefore, the present application provides a technique for producing a resist film having a high EUV light absorption rate and high shape stability.

### First Embodiment

### Method of Producing Resist Film

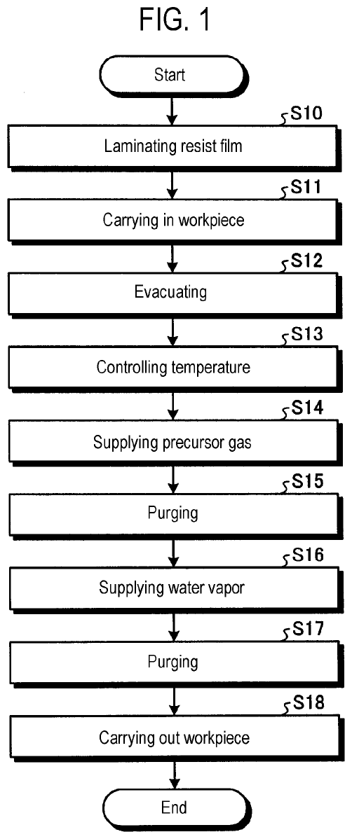

FIG. 1 is a flowchart illustrating an exemplary method of producing a resist film according to a first embodiment of the present disclosure.

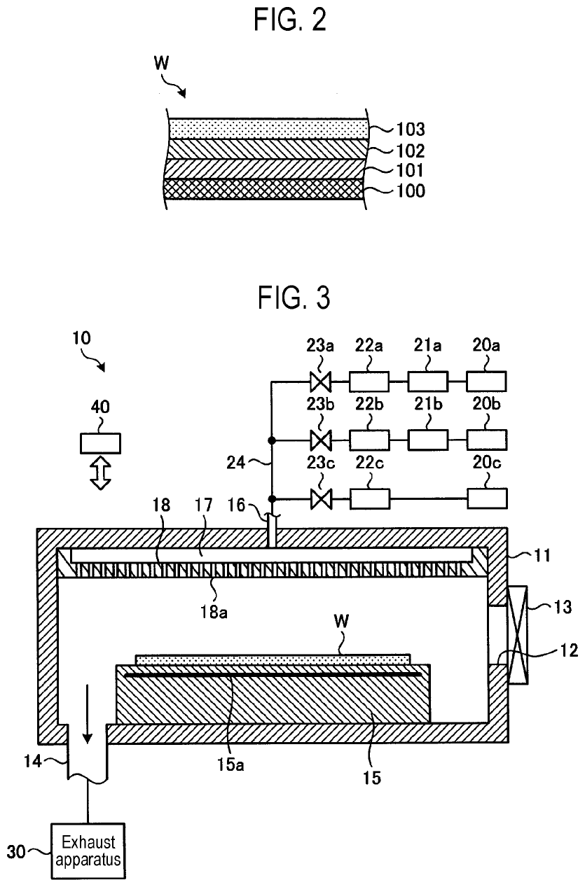

First, using a film forming apparatus (not illustrated), for example, spin-on-carbon (SOC) 101 and spin-on-glass (SOG) 102 are laminated on a silicon substrate 100, and a resist film 103 is laminated thereon (S10). As a result, for example, a workpiece W having a structure illustrated in FIG. 2 is fabricated. The SOC 101 and the SOG 102 are examples of etching target films. Step S10 is an example of a laminating process.

Next, the workpiece W is carried into, for example, a modification apparatus 10 illustrated in FIG. 3 (S11). FIG. 3 is a schematic cross-sectional view illustrating an exemplary modification apparatus 10. The modification apparatus 10 in the present embodiment modifies the resist film 103 by infiltrating a specific metal into the resist film 103 of the workpiece W. The modification apparatus 10 includes a chamber 11. An opening 12 is formed in the side wall of the chamber 11 so as to carry a workpiece W into the chamber 11 therethrough, and the opening 12 is opened and closed by a gate valve 13.

Inside the chamber 11, a stage 15 on which a workpiece W is placed is installed. The stage 15 includes a temperature control mechanism 15a, such as a heater, for controlling the temperature of the workpiece W to a predetermined temperature. The temperature control mechanism 15a is controlled by a controller 40, which will be described later.

In addition, an exhaust port 14 is installed in the bottom of the chamber 11, and an exhaust device 30, such as a vacuum pump, is connected to the exhaust port 14. By operating the exhaust device 30, the gas in the chamber 11 is exhausted through the exhaust port 14, so that the inside of the chamber 11 can be decompressed to a predetermined degree of vacuum. The exhaust device 30 is controlled by the controller 40, which will be described later.

A shower plate 18 is installed on the ceiling of the chamber 11 above the stage 15 so as to face the stage 15. The shower plate 18 includes ejection ports 18a penetrating the same in the thickness direction. The shower plate 18 is supported on the side wall of the chamber 11. A diffusion chamber 17 is formed between the shower plate 18 and the ceiling of the chamber 11. A pipe 16 is installed in the ceiling of the chamber 11 so as to supply gas into the diffusion chamber 17. The gas supplied into the diffusion chamber 17 via the pipe 16 diffuses in the diffusion chamber 17, and is supplied in the form of a shower to the underneath of the shower plate 18 via the ejection ports 18a.

Further, the modification apparatus 10 includes raw material supply sources 20a to 20c, vaporizers 21a to 21b, flow rate controllers 22a to 22c, and valves 23a to 23c. The raw material supply source 20a is a source of a precursor containing a metal to be infiltrated into the resist film 103. In the present embodiment, the metal infiltrated into the resist film 103 is a metal having a higher EUV light absorption rate than carbon.

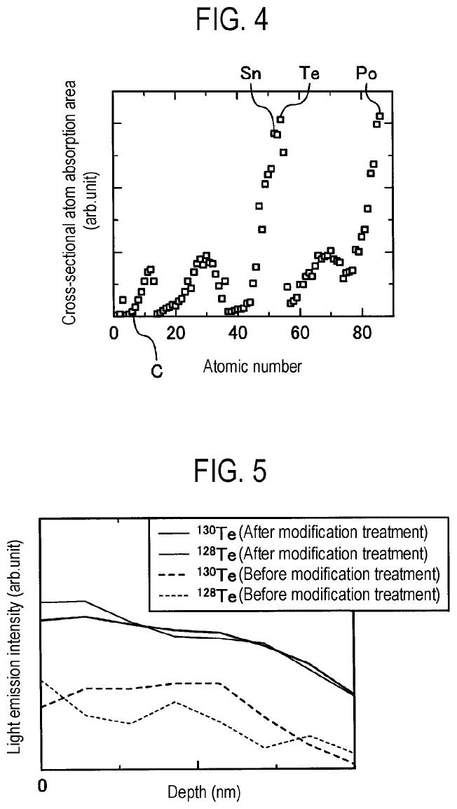

FIG. 4 is a diagram showing an exemplary EUV light absorption rate for each atom. When a metal having a higher EUV light absorption rate than carbon is infiltrated into the resist film 103, the metal-infiltrated resist film 103 is improved in the EUV absorption rate compared to the resist film 103 before the metal is infiltrated due to the influence of the infiltrated metal. As a result, in the resist film 103, the sensitivity to EUV light, which is an exposure light source, is improved, which enables formation of a fine pattern.

The metal to be infiltrated into the resist film 103 may be a metal having a higher EUV light absorption rate than carbon. As the EUV light absorption rate increases, it is possible to further reduce the exposure time and to save the power of the light source. As a metal having a high EUV light absorption rate, for example, polonium (Po) and tellurium (Te) are known as shown in FIG. 4. Considering the availability and the ease of handling of the material, the metal to be infiltrated into the resist film 103 is preferably tellurium or tin (Sn).

In the present embodiment, the metal infiltrated into the resist film 103 is, for example, tellurium, and the precursor is, for example, bis(trimethylsilyl)telluride. The precursor of tellurium may be, for example, diisopropyl tellurium. When the metal infiltrated into the resist film 103 is tin, the precursor may be, for example, tributyltin.

The vaporizer 21a vaporizes the precursor supplied from the raw material supply source 20a. In the present embodiment, the vaporizer 21a vaporizes the precursor by heating the same. The vaporizer 21a may vaporize a liquid precursor by bubbling using an inert gas such as nitrogen gas or argon gas. The flow rate controller 22a controls the flow rate of the vaporized precursor gas. The valve 23a controls the supplying and stopping of the supply of the precursor gas, the flow rate of which is controlled by the flow rate controller 22a, to the supply pipe 24. The precursor gas supplied to the supply pipe 24 is supplied into the chamber 11 via the pipe 16. The vaporizer 21a, the flow rate controller 22a, and the valve 23a are controlled by a controller 40, which will be described later.

The raw material supply source 20b is a supply source of liquid water. The vaporizer 21b vaporizes the water supplied from the raw material supply source 20b into water vapor. The flow rate controller 22b controls the flow rate of water vapor. The valve 23b controls the supplying and stopping of the supply of the water vapor, the flow rate of which is controlled by the flow rate controller 22b, to the supply pipe 24. The water vapor supplied to the supply pipe 24 is supplied into the chamber 11 via the pipe 16. The vaporizer 21b, the flow rate controller 22b, and the valve 23b are controlled by a controller 40, which will be described later.

The raw material supply source 20c is a supply source for an inert gas for purging the surface of a workpiece W. In the present embodiment, the inert gas for purging the surface of a workpiece W is, for example, nitrogen (N₂) gas. The flow rate controller 22c controls the flow rate of the inert gas supplied from the raw material supply source 20c. The valve 23c controls the supplying and stopping of the supply of the inert gas, the flow rate of which is controlled by the flow rate controller 22c, to the supply pipe 24. The inert gas supplied to the supply pipe 24 is supplied into the chamber 11 via the pipe 16. The flow rate controller 22c and the valve 23c are controlled by a controller 40, which will be described later.

The modification apparatus 10 includes a controller 40. The controller 40 has a memory, a processor, and an input/output interface. The processor in the controller 40 controls each part of the modification apparatus 10 via the input/output interface of the controller 40 by reading and executing a program or recipe stored in the memory in the controller 40.

Returning back to FIG. 1, a description will be continued. In step S11, the gate valve 13 is opened, and a workpiece W is carried into the chamber 11 by a transport mechanism (not illustrated) and is placed on the stage 15. Then, the transport mechanism is carried out of the chamber 11, and the gate valve 13 is closed.

Next, when the exhaust device 30 operates, the gas in the chamber 11 is exhausted, and the inside of the chamber 11 is evacuated (S12).

Next, the temperature control mechanism 15a in the stage 15 is controlled such that the temperature of the workpiece W becomes a predetermined temperature (S13).

Next, the valve 23a is opened, and the precursor gas, the flow rate of which is adjusted by the flow rate controller 22a, is supplied into the chamber 11 through the shower plate 18 (S14). As a result, metal-containing molecules contained in the precursor gas enter the resist film 103 of the workpiece W. Step S14 is an example of an infiltration step.

As the temperature of the workpiece W and the pressure in the chamber 11 increase, the amount of metal-containing molecules entering the resist film 103 increases. However, when the temperature and pressure are too high, the resist film 103 is changed to the glass state, and the lithography property in which solubility in a developing solution changes due to exposure is lost. In addition, when the amount of metal-containing molecules entering the resist film 103 is too large, the property of the metal become dominant and the lithography property of the resist film 103 is lost. Therefore, the amount of metal entering the resist film 103 is preferably 20 atomic % or less.

Therefore, it is preferable to perform the infiltration step under the following conditions.
Temperature of workpiece W: room temperature to 150 degrees C.
Pressure in chamber 11: 0.05 to 760 Torr
Flow rate of precursor gas: 5 to 500 sccm
Infiltration time: 3 to 30 minutes

Step S14 in the present embodiment is performed under, for example, the following conditions.
Temperature of workpiece W: 90 degrees C.
Pressure in chamber 11: 2 Torr
Flow rate of precursor gas: 10 sccm
Infiltration time: 30 minutes

When the precursor gas is gasified by bubbling, step S14 may be performed under, for example, the following conditions.
Temperature of workpiece W: 110 degrees C.
Pressure in chamber 11: 15 Torr
Flow rate of precursor gas: 500 sccm
Infiltration time: 3 minutes

Next, the valve 23a is closed, and the valve 23c is opened. Then, the inert gas, the flow rate of which is adjusted by the flow rate controller 22c, is supplied into the chamber 11 through the shower plate 18, and the molecules of the precursor excessively attached to the surface of the workpiece W are purged by the inert gas (S15). This makes it easier for water molecules to reach the precursor molecules, which have infiltrated into the resist film 103 in an exposure step, which will be described later. The flow rate of the inert gas in step S15 is, for example, 20 sccm. Step S15 is performed, for example, for 5 minutes. Step S15 is an example of a first purging step.

Next, the valve 23c is closed, and the valve 23b is opened. Then, the water vapor, the flow rate of which is adjusted by the flow rate controller 22b, is supplied into the chamber 11 through the shower plate 18 (S16). When the resist film 103 is exposed to the water vapor atmosphere, water molecules react with metal-containing molecules, which have entered the resist film 103, and atoms other than a target metal are bonded to hydroxyl groups or the like, thereby being separated from the resist film 103. As a result, it is possible to reduce impurities other than the target metal in the resist film 103. Step S16 is an example of an exposure step. In the following, the treatment in steps S14 to S17 may be referred to as modification treatment.

The exposure step is performed under, for example, the following conditions.
Temperature of workpiece W: room temperature to 150 degrees C.
Pressure in chamber 11: 0.05 to 760 Torr
Flow rate of water vapor: 10 to 100 sccm
Exposure time: 1 to 10 minutes

Step S16 in the present embodiment is performed under, for example, the following conditions.
Temperature of workpiece W: 90 degrees C.
Pressure in chamber 11: 2 Torr
Flow rate of water vapor: 10 sccm
Infiltration time: 10 minutes

In the infiltration step, when the precursor gas is gasified by bubbling, the exposure step of step S16 may be performed under, for example, the following conditions.
Temperature of workpiece W: 110 degrees C.
Pressure in chamber 11: 15 Torr
Flow rate of precursor gas: 100 sccm
Infiltration time: 1 minute

Next, the valve 23b is closed, and the valve 23c is opened. Then, the inert gas, the flow rate of which is adjusted by the flow rate controller 22c, is supplied into the chamber 11 through the shower plate 18 (S17). As a result, the molecules containing atoms, other than the target metal, separated from the resist film 103 are purged. The flow rate of the inert gas in step S17 is, for example, 20 sccm. Step S17 is performed, for example, for 5 minutes. Step S17 is an example of a second purging step.

Next, the gate valve 13 is opened, and the workpiece W is carried out of the chamber 11 by a transport mechanism (not illustrated) (S18). Then, the method of producing a resist film illustrated by this flowchart is terminated.

As described above, in the present embodiment, after the resist film 103 is formed, a metal having a higher EUV light absorption rate than carbon is infiltrated into the resist film 103, and thus it is possible to prevent the resist film 103 from gelling. Therefore, it is possible to improve the shape stability of the resist film 103. In the present embodiment, since a metal is infiltrated into the resist film 103 after the resist film 103 is formed, the infiltrated metal does not reduce the adhesion between the resist film 103 and the SOG 102. By infiltrating a metal into the resist film 103, it is possible to improve resistance to reactive ion etching.

### Resist Film after Infiltration

FIG. 5 is a diagram showing an exemplary tellurium distribution in the depth direction of a resist film 103. FIG. 5 shows light emission intensities of tellurium isotopes ¹²⁸Te and ¹³⁰Te. The resist film 103 before the modification treatment in the present embodiment contains a certain amount of tellurium, as shown by, for example, the thick broken line and the thin broken line in FIG. 5. In contrast, after the modification treatment, the amount of tellurium in the resist film 103 is larger than that before the modification treatment, as shown by, for example, the thick solid line and the thin solid line in FIG. 5. Therefore, it is possible to cause tellurium atoms to enter the resist film 103 by infiltration of a precursor gas and exposure to water vapor.

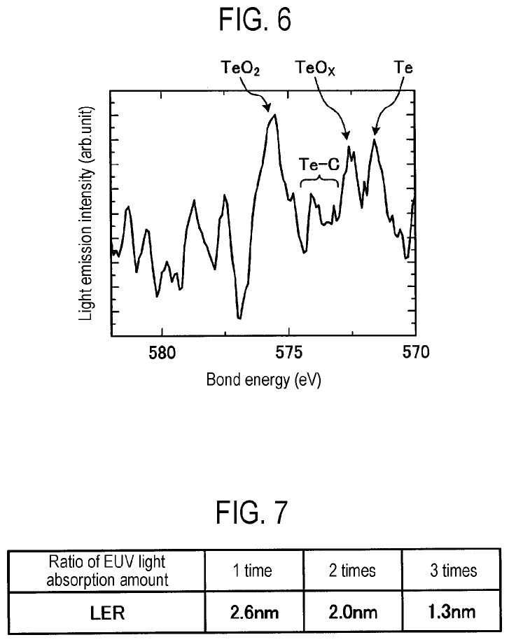

FIG. 6 is a diagram showing an exemplary light emission intensity for each bond energy in the resist film 103 after the modification treatment. For example, as shown in FIG. 6, in the resist film 103 after the modification treatment, a peak is observed in the light emission intensity of the bond energy corresponding to tellurium oxides (TeO₂, TeO_{X}) and the atoms of Te. Therefore, it can be seen that tellurium is present as an oxide or an atomic simple substance in the resist film 103 after the modification treatment.

Meanwhile, the bond energy between tellurium and carbon is about 573 to 574 eV, but referring to FIG. 6, the peak of light emission intensity representing the bond between tellurium and carbon is hardly seen. Therefore, it can be seen that when modification treatment is performed, tellurium atoms enter the resist film 103, but the bond between tellurium and carbon hardly occurs. Therefore, it is considered that functional groups, the solubility of which changes in the developing solution with exposure, remain as they are without being bonded to tellurium, and the lithography property of the resist film 103 is maintained even after the modification treatment.

By causing a metal such as tellurium, which has a higher EUV light absorption rate than carbon, to enter the resist film 103 by modification treatment, the sensitivity of the resist film 103 to EUV light is improved. As a result, the resist film 103 after modification treatment absorbs more EUV light than the resist film 103 before modification treatment.

FIG. 7 is a diagram showing an exemplary relationship between an EUV light absorption amount and line edge roughness (LER). In FIG. 7, the amount of EUV light absorbed by the resist film 103 before modification treatment is used as a reference (1 time). When the amount of absorbed EUV light is doubled by modification treatment, the LER is improved by about 25%. Further, when the amount of absorbed EUV light is tripled by modification treatment, the LER is improved by about 50%. When the amount of absorbed EUV light increases, a large amount of acid is generated in the resist film 103, and when a large amount of acid is generated, protective groups in the resist film 103 are removed and the resolution is improved. In this way, it is possible to improve the LER by increasing the EUV light absorption amount by modification treatment.

The first embodiment has been described above. The method of producing a resist film 103 in the present embodiment includes a laminating step and an infiltration step. In the laminating step, a workpiece W is fabricated by laminating the resist film 103 on an etching target film. In the infiltration step, a metal is infiltrated into the resist film 103 by exposing the workpiece W to a precursor gas containing a metal having a higher EUV light absorption rate than carbon. This makes it possible to increase the EUV light absorption rate in the resist film 103. In addition, since the metal is infiltrated into the resist film 103 after the resist film 103 is laminated, the shape stability of the resist film 103 can be maintained.

Further, in the embodiment described above, after the infiltration step, an exposure step of exposing the workpiece W to a water vapor atmosphere may be further executed. As a result, water molecules react with molecules of a metal-containing precursor, which has entered the resist film 103, and atoms other than a target metal are bonded to hydroxyl groups or the like and are separated from the resist film 103. As a result, it is possible to reduce impurities other than the target metal in the resist film 103.

In the above-described embodiment, the first purging step of purging the surface of a workpiece W using an inert gas may be executed after the infiltration step and before the exposure step. As a result, in the exposure step, it is easy for water molecules to reach the precursor molecules, which have infiltrated into the resist film 103, and the water molecules and the precursor molecules, which have entered the resist film 103, can be sufficiently reacted.

In the above-described embodiment, the second purging step of purging the surface of the workpiece W using an inert gas may be executed after the exposure step. This makes it possible to remove impurities, other than the target metal, produced by reacting with water molecules in the exposure step.

In addition, in the above-described embodiment, the metal infiltrated into the resist film 103 may be tin or tellurium. This makes it possible to significantly increase the EUV light absorption rate in the resist film 103.

In the above-described embodiment, when the metal infiltrated into the resist film 103 is tin, the precursor may be tributyltin. When the metal infiltrated into the resist film 103 is tellurium, the precursor may be bis(trimethylsilyl)telluride or diisopropyl tellurium. This makes it possible to infiltrate tin or tellurium into the resist film 103.

### Second Embodiment

In the method for producing a resist film 103 of the first embodiment, the infiltration step and the exposure step were each performed once. The present embodiment is different from the first embodiment in that, in the method for producing a resist film 103 of the present embodiment, the infiltration step and the exposure step are alternately performed twice or more.

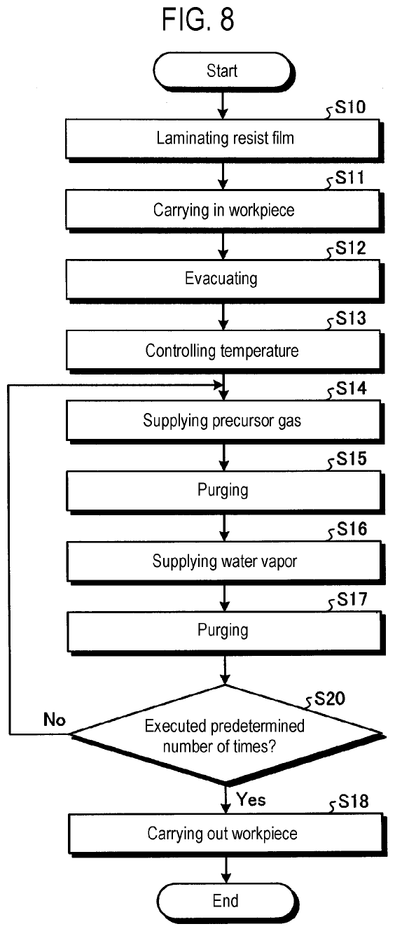

FIG. 8 is a flowchart illustrating an exemplary method of producing a resist film according to a second embodiment of the present disclosure. Except for the points described below, in FIG. 8, the processes denoted with the same reference numerals as those in FIG. 1 are the same as those described with reference to FIG. 1, and thus a description thereof will be omitted.

In step S14, the resist film 103 is exposed to the precursor gas, and the molecules of the precursor gas are infiltrated into the resist film 103. Step S14 in the present embodiment is performed under, for example, the following conditions.
Temperature of workpiece W: 90 degrees C.
Pressure in chamber 11: 2 Torr
Flow rate of precursor gas: 10 sccm
Infiltration time: 15 minutes

When the precursor gas is gasified by bubbling, step S14 may be performed under, for example, the following conditions.
Temperature of workpiece W: 110 degrees C.
Pressure in chamber 11: 15 Torr
Flow rate of precursor gas: 500 sccm
Infiltration time: 90 seconds

Next, purging with an inert gas is performed (S15), and the resist film 103 is exposed to water vapor (S16). Then, purging with an inert gas is performed (S17). Step S16 in the present embodiment is performed under, for example, the following conditions.
Temperature of workpiece W: 90 degrees C.
Pressure in chamber 11: 2 Torr
Flow rate of water vapor: 10 sccm
Infiltration time: 5 minutes
In the infiltration step, when the precursor gas is gasified by bubbling, step S16 may be performed under, for example, the following conditions.
Temperature of workpiece W: 110 degrees C.
Pressure in chamber 11: 15 Torr
Flow rate of precursor gas: 100 sccm
Infiltration time: 30 seconds

Next, it is determined whether or not steps S14 to S17 have been executed a predetermined number of times (S20). In this embodiment, the predetermined number of times is, for example, twice. In addition, the predetermined number of times may be, for example, three times or more. When steps S14 to S17 have not been executed the predetermined number of times (S20: “No”), the process illustrated in step S14 is executed again. Meanwhile, when steps S14 to S17 have been executed the predetermined number of times (S20: “Yes”), the process illustrated in step S18 is executed.

Here, by executing the exposure step, it is possible to cause atoms, other than the target metal, to be bonded to hydroxyl groups or the like from the molecules of the precursor gas, which have entered the resist film 103 in the infiltration step, to be separated from the resist film 103. When the atoms other than the target metal are separated from the resist film 103, voids are generated in the resist film 103 due to the separation of the atoms. Thus, more molecules of the precursor gas are capable of entering the resist film 103 by the next infiltration step. By alternately repeating the infiltration step and the exposure step twice or more in this way, it is possible to efficiently infiltrate the target metal into the resist film 103.

The second embodiment has been described above. In the method for producing a resist film 103 in the present embodiment, the infiltration step, the first purging step, the exposure step, and the second purging step are repeated twice or more in that order. This makes it possible to efficiently infiltrate the target metal into the resist film 103.

### Others

The technology disclosed herein is not limited to the embodiment described above, and various modifications are possible within the scope of the gist the present disclosure.

For example, in each of the above-described embodiments, tellurium and tin have been described as examples of the metals to be infiltrated into the resist film 103, but the disclosed technology is not limited thereto. The metal to be infiltrated into the resist film 103 may be, for example, sodium, magnesium, or aluminum when the metal is a light element, and may be, for example, indium, antimony, or cesium when the metal is a heavy element.

It shall be understood that the embodiments disclosed herein are illustrative and are not restrictive in all aspects. Indeed, the above-described embodiments can be implemented in various forms. The embodiments described above may be omitted, replaced, or modified in various forms without departing from the scope and spirit of the appended claims.

### EXPLANATION OF REFERENCE NUMERALS

W: workpiece, 10: modification apparatus, 11: chamber, 12: opening, 13: gate valve, 14: exhaust port, 15: stage, 15a: temperature control mechanism, 16: pipe, 17: diffusion chamber, 18: shower plate, 18a: ejection port, 20a, 20b, 20c: raw material supply source, 21a, 21b: vaporizer, 22a, 22b, 22c: flow rate controller, 23a, 23b, 23c: valve, 24: supply pipe, 100: silicon substrate, 101: SOC, 102: SOG, 103: resist film, 30: exhaust device, 40: controller

1. A method of producing a resist film, the method comprising:
a laminating step of fabricating a workpiece by laminating the resist film on an etching target film; and
an infiltration step of exposing the workpiece to a gas of a precursor containing a metal having a higher EUV light absorption rate than carbon to infiltrate the metal into the resist film.

2. The method of claim 1, further comprising:
an exposure step of exposing the workpiece to a water vapor after the infiltration step.

3. The method of claim 2, further comprising:
a first purging step of purging a surface of the workpiece using an inert gas after the infiltration step and before the exposure step.

4. The method of claim 3, further comprising:
a second purging step of purging the surface of the workpiece using the inert gas after the exposure step.

5. The method of claim 4, wherein the infiltration step, the first purging step, the exposure step, and the second purging step are repeated twice or more in that order.

6. The method of claim 1, wherein the metal is one selected from a group consisting of tin and tellurium.

7. The method of claim 1, wherein the precursor is one selected from a group consisting of tributyltin, bis(trimethylsilyl)telluride, and diisopropyl tellurium.

8. The method of claim 1, wherein the metal is one selected from a group consisting of sodium, magnesium and aluminum.

9. The method of claim 1, wherein the metal is one selected from a group consisting of indium, antimony and cesium.
